(19) United States
(12) Patent Application Publication
(10) Pub. No.: US 2003/0066942 A1
(43) Pub. Date: Apr. 10, 2003

(54) Shock attenuating platform for electronic devices

(76) Inventor: Michael Frederick Stierheim, Orlando, FL (US)

Correspondence Address: GREENBERG-TRAURIG, 1750 TYSONS BOULEVARD, 12TH FLOOR, MCLEAN, VA, 22102, US

(21) Appl. No.: 09/971,059

(22) Filed: Oct. 5, 2001

(51) Int. Cl. F16M 13/00; H05K 7/02; H05K 7/04

(52) U.S. Cl. 248/560; 361/807

(57) ABSTRACT

A shock and vibration resistant platform for mounting sensitive electronic devices on person vehicles. Shock attenuation is provide by a spring loaded central shaft bearing the electronic device platform. Vertical movement is dampened by the spring action. In a preferred embodiment, a weight is used to bring the platform back to a preferred location to prevent rotation of the platform.

### FIELD OF THE INVENTION

The present invention relates in general to the mounting of electronic devices and in particular to a shock resistant and vibration dampening platform for mounting electronic devices on personal vehicles.

### BACKGROUND OF THE INVENTION

With the popularity of electronic equipment such as compact disc players, MP3 players, GPS Units, radar detectors, mini-TV's, etc., there is a desire to use these electronic devices while operating personal vehicles such as bicycles, motorcycles, ATVs, snowmobiles, jet skis, or the like. The use of such electronic devices on a vehicle which may turn sharply, accelerate, de-accelerate or be subjected to jars or impact due to the terrain, places high demands on the electronic devices which may cause them to skip tracks, or not operate properly or otherwise damage the electronic devices. What is needed is a mounting platform for sensitive electronic devices on personal vehicles providing attenuation of shock and vibration.

### SUMMARY OF THE INVENTION

Accordingly, the present invention is a shock resistant and vibration dampening electronic platform designed to be mounted on personal vehicles for road or off-road use. It is comprised of a mounting bracket designed primarily to be attached to the handlebar of a personal vehicle. The bracket may be held in place by an action which grips around or is squeezed between a part of the personal vehicle such as a handle bar. A shock dampening platform is secured to the mounting bracket. The shock dampening platform employs a spring action shock absorber surrounding a central, generally vertical, shaft. The central shaft is mounted on a distal end of the universal mounting bracket.

A sleeve is attached to the distal end of the mounting bracket. The sleeve has no range of motion and can be incorporated as a part of the mounting bracket. A central shaft is tightly fit through the sleeve allowing for movement up and down but not side to side. Above and below the sleeve and curled around the shaft are springs. The springs are kept under compressive tension to resist vertical movement of the shaft. When the shaft travels up and down in the sleeve, the springs extend on the bottom and compress on the top (or visa versa). This spring action absorbs energy caused by shock such as hitting a pothole on a bicycle. The springs then return to a state of equal pressure on the top and the bottom of the sleeve to center the shaft vertically on its mounting.

A platform secured to the top of the shaft is used as a mount for the attachment of electronic devices. The platform can be a separate unit secured to the shaft using conventional hardware or it can be a unitary part of the shaft. Rubber, foam or other vibration dampening material can be incorporated into the design of the platform. The platform may also have a counter weight wherein the platform is returned to the lowest center of gravity preventing the platform from rotating. This prevents entanglement of any wires attached to the electronic devices and provides easier use of the electronic equipment.

### BRIEF DESCRIPTION OF THE DRAWINGS

The accompanying drawings, which are included to provide a further understanding of the invention, are incorporated in, and constitute a part of this specification, illustrate embodiments of the invention and together with the description serve to explain the principles of the invention.

In the drawings:

FIG. 1a is a perspective drawing showing a mounting bracket according to the present invention.

FIG. 1b is a drawing showing an alternative mounting bracket according to the present invention.

FIG. 2 is a perspective view of the shock attenuating platform of the present invention.

FIG. 3 illustrates the use of a counter weight to further stabilize the present invention.

### DETAILED DESCRIPTION OF THE PREFERRED EMBODIMENT

Reference will now be made in detail to the preferred embodiments of the present invention, examples of which are illustrated in the accompanying drawings.

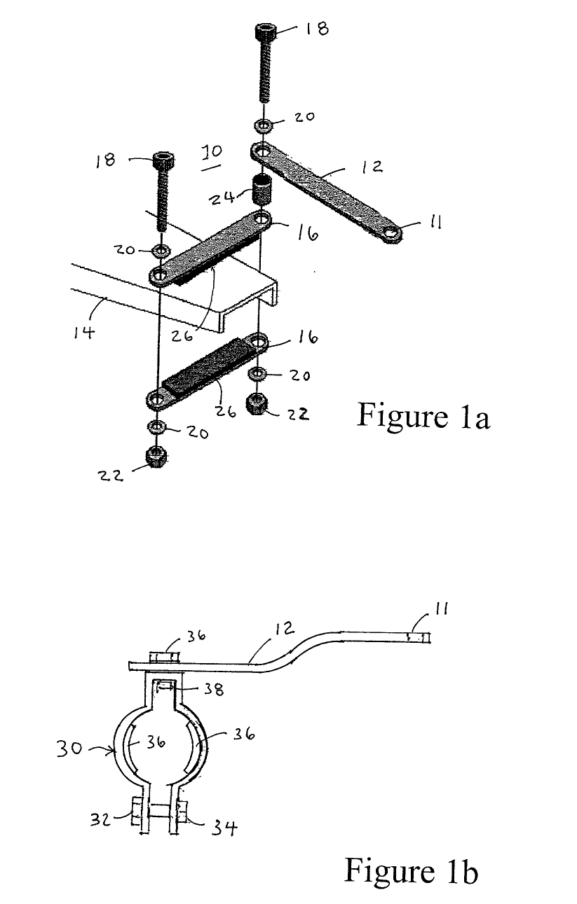

Illustrated in FIG. 1 is a mounting bracket 10 having a support arm 12 on which the shock dampening platform can be attached. The mounting bracket 10 can be mounted to a portion of a personal vehicle 14 by use of cross bars 16 which are clamped to the personal vehicle 14 by use of bolts 18, washers 20, and nuts 22. A spacer 24 can be used to position the support arm 12 at various heights and promote a tighter clamp of the support arm 12 to the personal vehicle 14. The cross bars 16 may have a strip of vibration dampening material, such as foam 26, between the personal vehicle 14 and the cross bars 16. A hole 11 is positioned at the distal end of the support arm 12 for holding the electronic device mounting platform. Support arm 12 may be bent in a shape to position the electronics platform in a preferred manner.

An alternative mounting bracket specially adapted for mounting to the handle bar of a personal vehicle is shown in FIG. 1b. Mounting clamp 30 may be secured to the handle bar of a personal vehicle (not shown) with a bolt 32 and nut 34. Vibration dampening material 36, such as a foam rubber, may be placed on the clamp 30 to increase the vibration dampening between the vehicle and the mounting bracket. A bolt and nut 36 and 38, respectively, secures the support arm 12 onto the mounting clamp. At the distal end of support arm 12 is a hole 11 to receive the electronics platform.

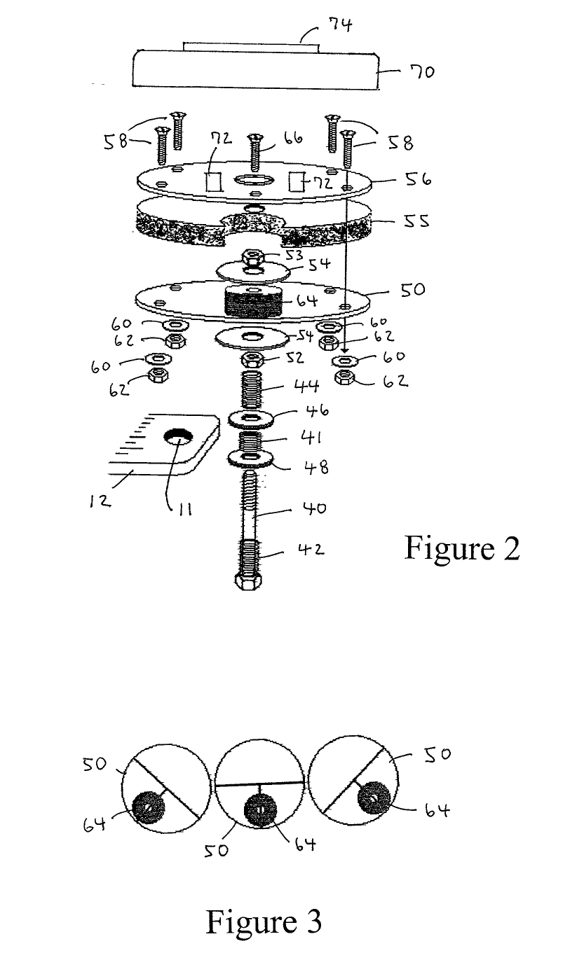

An exploded view of the electronics platform is shown in FIG. 2. The electronic device mounting platform is designed to be attached on the distal end of the support arm 12 through hole 11. A threaded sleeve 41 having an outer diameter of substantially the size of the hole 11 and an inner diameter of substantially the size of bolt 40 used to form the central shaft is positioned in the support arm 12 through hole 11. Knurl nuts 46 and 48 or the like can be threaded onto the threaded sleeve 41 to secure its position on the support arm 12.

A central shaft, positioned substantially in a vertical direction, is formed by a bolt 40 inserted through the threaded sleeve 41. A first spring 42 and second spring 44 are positioned on bolt 40 below and above the threaded sleeve. A nut 52 can be used to secure the bolt 40 onto threaded sleeve 41. This allows shaft 40 upward and downward movement through the mounting bracket. The springs are placed under compressive tension to resist movement of the central shaft in either an upward or downward direction to thereby absorb shock upon the central shaft. Attached on the threaded end of bolt 40 is a platform upon which electronic devices can be mounted.

The platform 50 can be mounted using nut 53 and washers 54. The platform 50 can be made of aluminum or it can be made of plastic and is designed to support personal electronic devices.

In a preferred embodiment, secondary platform 56 is attached to platform 50, spaced apart by vibration dampening material 55, such as a foam rubber, which further dampens vibration and absorbs shock. The secondary platform 56 may be plastic, aluminum or other metal and secured to the first platform 50 by bolts 58, washers 60 and nuts 62.

Another feature of the present invention is the addition of a weight 64 which may be attached to either platform 50 or platform 56 using a bolt 66 having a nut and a washer (not shown) or alternatively the weight could be held on by glue or epoxy. The operation of the weight is shown in FIG. 3 wherein the weight brings the platform to a centered, lowest point of gravity position. If the shaft is generally at an angle of slightly less than 90 degrees from the ground, there will be a gravitational pull on the weight 64 to bring the platform 50 back to a specific position. This will prevent the electronics mounted on the platform from spinning and avoid any entanglement of electrical wires, such as earphone wires or power supply wires, and allows easier use of the electronic device whose operational controls will generally be in the same position.

A cap 70 can be placed over the electronics platform as protection for the platform or as a decorative cap. The cap may be out of plastic or metal and could be chrome plated for decorative purposes. The cap can be mounted to the secondary platform 56 via interlocking fastening tape 72 such as Velcro™. It is envisioned that Velcro™ can also be used on the top surface of the cap to hold electronic equipment. The Velcro™ shown as element 74 allows quick fastening and removal of components.

While the invention has been described in detail and with reference to specific embodiments thereof, it will be apparent to those skilled in the art that various changes and modifications can be made therein without departing from the spirit and scope thereof. For example, the materials used can be metal or various types of plastic. The means of securing the parts together can be bolts, welds, glues, rivets or the like. Thus, it is intended that the present invention cover the modifications and variations of this invention provided they come within the scope of the appended claims and their equivalents.

What is claimed is:

1. A shock attenuating platform for mounting electronic devices on a vehicle comprising:
a support bracket rigidly mounted upon said vehicle;
a central shaft supported at a distal end of said the support bracket having movement only substantially perpendicular to said support bracket;
shock absorbing springs surrounding said central shaft in communication therewith to dampen movement perpendicular to said support bracket; and
a platform for mounting of electronic devices thereon secured to said central shaft.

2. The shock attenuating platform of claim 1 wherein vibration damping material is interposed between the support bracket and the vehicle.

3. The shock attenuating platform of claim 1 wherein the support bracket is formed of a unitary u-shaped member and an extending support arm.

4. A shock attenuating platform for mounting electronic devices on a vehicle comprising:
a support bracket rigidly mounted upon said vehicle;
a central shaft supported at a distal end of said the support bracket having movement only substantially perpendicular to said support bracket;
shock absorbing springs surrounding said central shaft in communication therewith to dampen movement perpendicular to said support bracket;
a first platform secured to an upper end of said central shaft; and
a second platform spaced-apart from and non-rigidly attached to the first platform for the mounting of electronic devices.

5. The shock attenuating platform of claim 4 wherein vibration absorbing material is interposed between first and second platforms.

6. The shock attenuating platform of claim 4 wherein a decorative cap is positioned over the second platform.

7. The shock attenuating platform of claim 4 wherein the decorative cap is secured by Velcro™.

8. The shock attenuating platform of claim 6 wherein Velcro™ is used to secure electronic devices to the decorative cap.

9. A shock attenuating platform for mounting electronic devices on a vehicle comprising:
a support bracket rigidly mounted upon said vehicle;
a central shaft supported at a distal end of said the support bracket having movement only substantially perpendicular to said support bracket;
shock absorbing springs surrounding said central shaft in communication therewith to dampen movement perpendicular to said support bracket;
a platform for mounting of electronic devices thereon secured to said central shaft; and
a weight secured to the platform for rotating the central shaft to return the platform to a position at its lowest center of gravity.

10. The shock attenuating platform of claim 9 having a first platform secured to said central shaft and a second platform spaced-apart from and non-rigidly attached to said first platform for the mounting of electronic devices.

11. The shock attenuating platform of claim 10 wherein the weight is secured between the spaced-apart platforms.

12. The shock attenuating platform of claim 11 wherein a decorative cap covers the second platform.

13. A shock attenuating platform for mounting electronic devices on a vehicle comprising:
a support bracket rigidly mounted upon said vehicle;
a central shaft supported at a distal end of said the support bracket having movement only substantially perpendicular to said support bracket;
shock absorbing springs surrounding said central shaft in communication therewith to dampen movement perpendicular to said support bracket;
a first platform secured to said central shaft;
a second platform spaced-apart from and non-rigidly attached to the first platform for the mounting of electronic device; and
a weight secured to one of the platforms for rotating the central shaft to return the platform to a position at its lowest center of gravity.

14. The shock attenuating platform of claim 13 wherein vibration absorbing material is placed between first and second platforms.

15. The shock attenuating platform of claim 13 wherein a decorative cap is positioned over the second platform.

16. The shock attenuating platform of claim 15 wherein the decorative cap is secured by Velcro™.

17. The shock attenuating platform of claim 15 wherein Velcro™ is used to secure electronic devices to the decorative cap.
